(19) United States
(12) Patent Application Publication
(10) Pub. No.: US 2021/0020635 A1
(43) Pub. Date: Jan. 21, 2021

(54) SEMICONDUCTOR STRUCTURE AND METHOD OF FORMATION

(71) Applicant: NANYA TECHNOLOGY CORPORATION, New Taipei City (TW)

(72) Inventor: YI-HSIEN CHOU, TAOYUAN CITY (TW)

(21) Appl. No.: 16/514,327

(22) Filed: Jul. 17, 2019

(51) Int. Cl. H01L 27/092; H01L 29/66; H01L 29/78; H01L 21/8238

(52) U.S. Cl. CPC H01L 27/0924; H01L 29/66795; H01L 21/823878; H01L 21/823821; H01L 29/785

(57) ABSTRACT

The present disclosure provides a semiconductor structure and a method of forming the same. The semiconductor structure includes a substrate, a first device, a second device, a fin, a first gate dielectric layer, a second gate dielectric layer, and a cut region of the fin. The second device is adjacent to the first device. The fin is disposed on the substrate between the first device and the second device. The first gate dielectric layer is disposed on a first portion of the fin, and the second gate dielectric layer is disposed on a second portion of the fin. The cut region of the fin is formed within a trench between the first device and the second device.

### TECHNICAL FIELD

The present disclosure relates to a semiconductor structure and a method of forming the same, and more particularly, to structures and methods in which fins include a cut region within a trench between adjacent devices.

### DISCUSSION OF THE BACKGROUND

The modern integrated circuit (IC) includes a very large number of circuit elements in a restricted chip area. As the semiconductor IC industry continues to improve the integration density of electronic components by continual reductions in minimum feature size, more components are being integrated into the given area.

These integration improvements are essentially two-dimensional (2D) in nature, in that the volume occupied by the integrated components is essentially on the surface of the semiconductor wafer. Although dramatic improvements in lithography have resulted in considerable improvements in 2D integrated circuit formation, there are physical limitations to the density that can be achieved in two dimensions. One of these limitations is the minimum size needed to make these components. Such scaling down has also increased the complexity of processing and manufacturing ICs and, for continuing advances to be realized, similar developments in IC manufacturing are needed.

In the pursuit of greater device density, better performance, and lower costs, challenges in both fabrication and design have resulted in the development of 3D FinFET devices. As the dimensions of the fins of these devices become smaller, the creation of isolation structures before the formation of fins becomes problematic. When semiconductor material is formed on exposed portions of the fins not covered by gates, the cut portions of the fins suffer from non-uniformity compared to other un-cut portions of the fins. Moreover, as the scaling down continues, it is increasingly difficult to control the threshold voltages of adjacent FinFET devices.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure, including a substrate, a first device, a second device, a fin, a first gate dielectric layer, a second gate dielectric layer, and a cut region of the fin. The second device is adjacent to the first device. The fin is disposed on the substrate between the first device and the second device. The first gate dielectric layer is disposed on a first portion of the fin, and the second gate dielectric layer is disposed on a second portion of the fin. The cut region of the fin is formed within a trench between the first device and the second device.

In some embodiments, the first gate dielectric layer and the second gate dielectric layer comprise a high-k dielectric material.

In some embodiments, the cut region of the fin separates the first gate dielectric layer and the second gate dielectric layer, with the first gate dielectric layer remaining on the first device, and the second gate dielectric layer remaining on the second device.

In some embodiments, the first gate dielectric layer and the second gate dielectric layer are discontinuous in the cut region of the fin.

In some embodiments, the first device and the second device do not share a common gate dielectric layer.

In some embodiments, the first device is an n-type fin field-effect transistor (FinFET), and the second device is a p-type FinFET.

In some embodiments, an insulator material is disposed in the cut region of the fin.

In some embodiments, a shallow trench isolation (STI) structure is formed in the insulator material.

In some embodiments, a gate electrode is disposed on a high-work-function metal of the second device.

In some embodiments, a gate metal is disposed on the gate electrode.

In some embodiments, the cut region of the fin blocks an oxygen transport pathway from the p-type FinFET to the n-type FinFET.

In some embodiments, the cut region of the fin preserves a threshold voltage of the first device.

Another aspect of the present disclosure provides a method of forming a semiconductor structure, including providing a substrate; forming a fin on the substrate; forming a first gate dielectric layer on a first portion of the fin; forming a second gate dielectric layer on a second portion of the fin; forming a patterned mask layer on the first gate dielectric layer and the second gate dielectric layer; and etching an exposed portion of the fin to provide a cut region within a trench between a first device and a second device, wherein the second device is adjacent to the first device.

In some embodiments, the first gate dielectric layer and the second gate dielectric layer comprise high-k dielectric material.

In some embodiments, the cut region of the fin layer separates the first gate dielectric layer and the second gate dielectric layer, with the first gate dielectric layer remaining on the first device, and the second gate dielectric layer remaining on the second device.

In some embodiments, the first device is an n-type fin field-effect transistor (FinFET), and the second device is a p-type FinFET.

In some embodiments, an insulator material is disposed in the cut region of the fin.

In some embodiments, a shallow trench isolation (STI) structure is formed in the insulator material.

In some embodiments, a gate electrode is disposed on a high-work-function metal of the second device.

In some embodiments, a gate metal is disposed on the gate electrode.

Because the fins in the semiconductor structure of the present disclosure are not cut until after the source/drain regions are formed on the fins, it is preferable that the semiconductor material of the source/drain regions be consistent across all of the FinFET devices. Moreover, the isolation structures in the cut region of the fins are able to laterally isolate the active FinFET devices. In the semiconductor structure of the present disclosure, the first gate dielectric layer and the second gate dielectric layer are discontinuous in the cut region of the fins, and the FinFET devices do not share a common gate dielectric layer. The fins of the semiconductor structure are cut before the deposition of the high-work-function metals for the FinFET devices. Accordingly, diffusion of oxygen from the p-type FinFET devices to the n-type FinFET devices can be stopped, thereby enabling threshold voltage control for the FinFET devices in the semiconductor structure.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a plan view depicting a semiconductor structure according to some embodiments of the present disclosure;

FIG. 2 is a cross-sectional view depicting the semiconductor structure along a line A-A′ in FIG. 1 according to some embodiments of the present disclosure;

FIG. 3 is a flow diagram depicting a method of forming a semiconductor structure in accordance with some embodiments of the present disclosure; and

FIG. 4 to FIG. 7 are cross-sectional views illustrating various fabrication stages constructed according to a method of forming a semiconductor structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing is particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

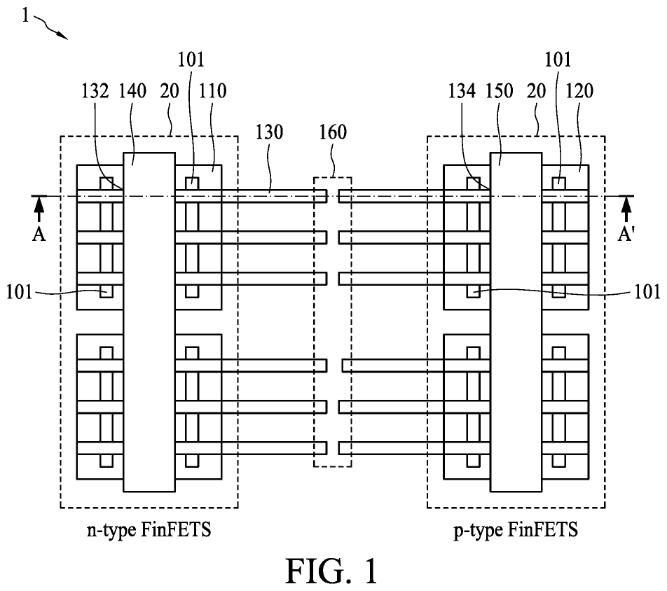

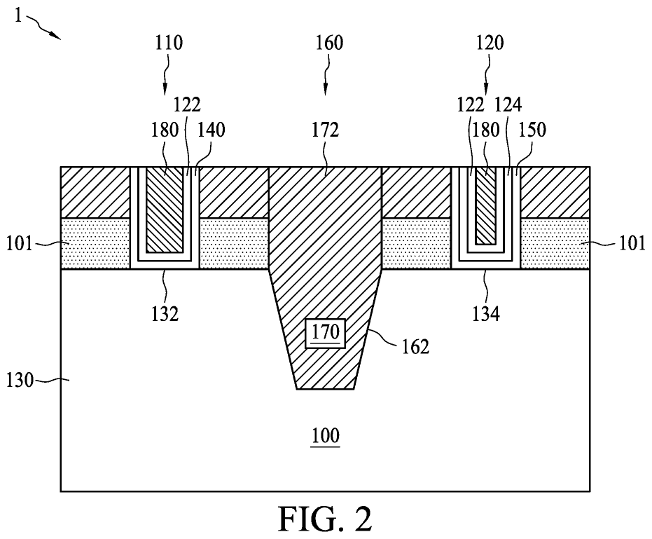

In accordance with some embodiments of the disclosure, FIG. 1 is a plan view depicting a semiconductor structure 1 according to some embodiments of the present disclosure, and FIG. 2 is a cross-sectional view depicting the semiconductor structure 1 along a line A-A′ in FIG. 1 according to some embodiments of the present disclosure. With reference to FIG. 1 and FIG. 2, in some embodiments, the semiconductor structure 1 includes a substrate 100, a first device 110, a second device 120, a plurality of fins 130, a first gate dielectric layer 140, a second gate dielectric layer 150, and a cut region 160 of the fins 130. The second device 120 is adjacent to the first device 110. The fins 130 are disposed on the substrate 100 between the first device 110 and the second device 120. In some embodiments, the first gate dielectric layer 140 is disposed on a first portion 132 of the fins 130, and the second gate dielectric layer 150 is disposed on a second portion 134 of the fins 130. Source/drain regions 101 of the first device 110 and the second device 120 are disposed on the fins 130. In some embodiments, the cut region 160 of the fins 130 is formed within a trench 162 between the first device 110 and the second device 120.

In some embodiments, the first gate dielectric layer 140 and the second gate dielectric layer 150 may include a high-k dielectric material, such as Al₂O₃, HfO₂, Ta₂O₃, TiO₂, La₂O₃, SrTiO₃, LaAlO₃, Gd₂O₃, Y₂O₃, ZrO₂, or a combination including multi-layers thereof. In some embodiments, the cut region 160 of the fins 130 separates the first gate dielectric layer 140 and the second gate dielectric layer 150, with the first gate dielectric layer 140 remaining on the first device 110, and the second gate dielectric layer 150 remaining on the second device 120. Moreover, the first gate dielectric layer 140 and the second gate dielectric layer 150 are discontinuous in the cut region 160 of the fins 130, and the first device 110 and the second device 120 do not share a common gate dielectric layer. In some embodiments, the first device 110 is an n-type fin field-effect transistor (FinFET), and the second device 120 is a p-type FinFET.

In some embodiments, an insulator material 170 is disposed in the cut region 160 of the fins 130. A shallow trench isolation (STI) structure 172 may be formed in the insulator material 170. In some embodiments, a gate electrode 122 is disposed on a high-work-function metal 124 of the second device 120 (p-type FinFET). In some embodiments, a gate metal 180 is disposed on the gate electrode 122.

In some embodiments, the cut region 160 of the fins 130 blocks an oxygen transport pathway from the second device 120 (p-type FinFET) to the first device 110 (n-type FinFET). In some embodiments, the cut region of the 160 of the fins 130 preserves a threshold voltage Vt of the first device 110 (n-type FinFET).

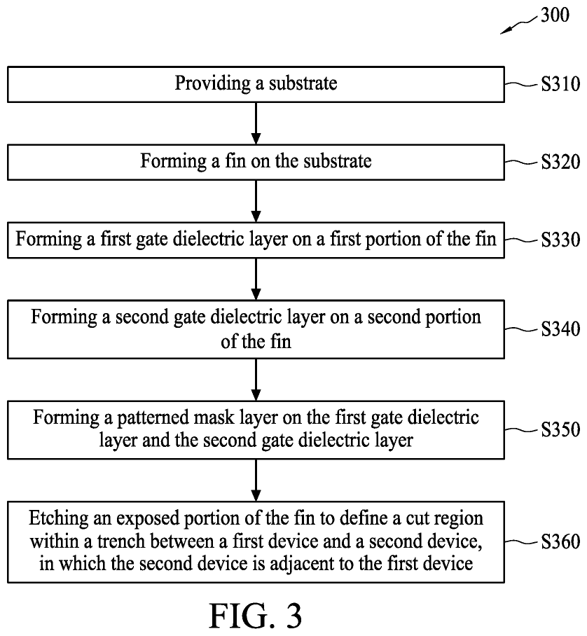

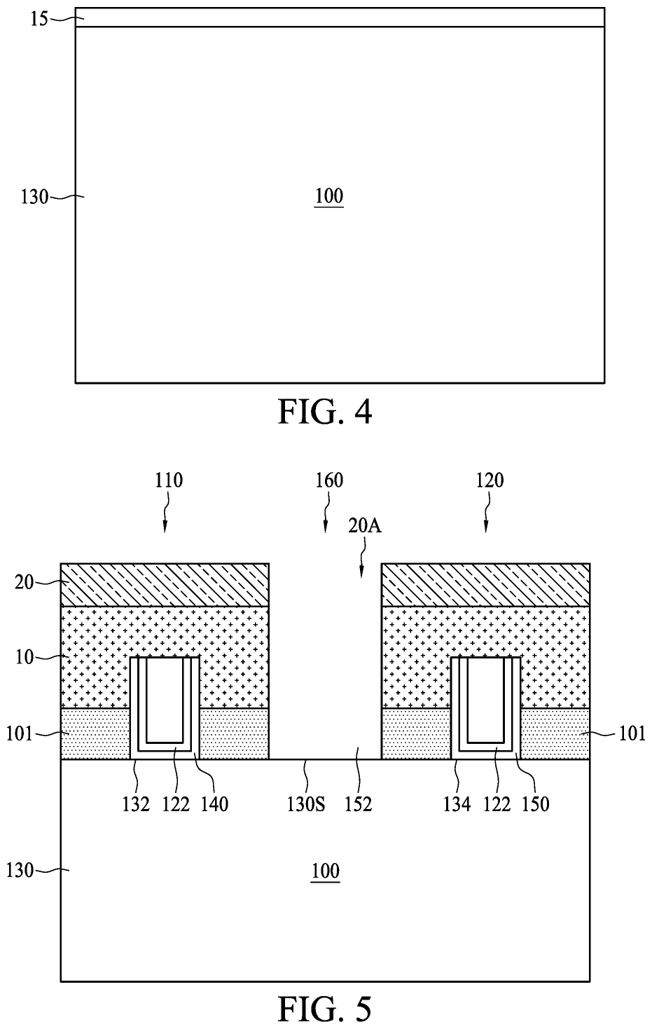

FIG. 3 is a flow diagram depicting a method 300 of forming a semiconductor structure 1 in accordance with some embodiments of the present disclosure. FIG. 4 to FIG. 7 are cross-sectional views along the line A-A′ of FIG. 1 illustrating various fabrication stages constructed according to the method 300 of forming the semiconductor structure 1 in accordance with some embodiments of the present disclosure. The stages shown in FIG. 4 to FIG. 7 are also illustrated schematically in the flow diagram of FIG. 3. In the subsequent discussion, the fabrication stages shown in FIG. 4 to FIG. 7 are discussed in reference to the process steps in FIG. 3.

Referring to FIG. 4, a substrate 100 is provided according to a step S310 in FIG. 3. In a step S320, a fin 130 is formed on the substrate 100. As shown in FIG. 4, to form the fin 130, a mask layer 15 may be deposited on substrate 100. The mask layer 15 may be a patterned etch mask formed on the substrate 100, for example, such as a combination of a silicon dioxide layer and a silicon nitride layer (not separately shown). One or more etching processes may be performed through the mask layer so as to define and form the fins 130 extending across the entire semiconductor structure 1, as shown in the plan view of FIG. 1. As will be recognized by those skilled in the art, the structures and methods disclosed herein may be employed when manufacturing semiconductor structures having any number of fins 130. Moreover, as depicted in FIG. 1, the fins 130 extend laterally in the current transport direction of the semiconductor structure 1 and into the source/drain regions 101 of the first device 110 and second device 120.

In some embodiments, the substrate 100 may include any suitable material including, but not limited to, Si, SiC, SiGe, SiGeC, GaAs, InP, InAs, or other II/VI or III/V compound semiconductors. The fins 130 may also be formed by other suitable sidewall imaging techniques known to those skilled in the art. The mask layer 15 may be deposited by conventional deposition processes, such as chemical vapor deposition (CVD). Reactive ion etching and/or conventional etching processes may be used to form and then remove mandrels. Depending on the application, the fins 130 may have a pitch of 45 nm or less. In some embodiments, the substrate 100 may also include other components such as transistors, resistors, capacitors, diodes, etc. In some embodiments, the substrate 100 may further include an interconnection structure (not shown), including alternating stacking of wiring layers and vias disposed over the components, and one or more interlayer dielectrics encircling the wiring layers and the vias (not shown). The substrate 100 may include a semiconductor wafer, semiconductor chip, or wafer portion, for example. The substrate 100 may include a plurality of alternating dielectric and metal interconnect layers overlying an upper metal layer (not shown). It should be noted that the substrate 100 may also be any of a variety of other structures known to those skilled in the art including, but not limited to, ceramic and organic based substrates.

With reference to FIG. 5, in some embodiments, a first gate dielectric layer 140 is formed on a first portion 132 of the fin 130, according to a step S330 in FIG. 3. In a step S340, a second gate dielectric layer 150 is formed on a second portion 134 of the fin 130. In a step S350, a patterned mask layer 20 is formed on the first gate dielectric layer 140 and the second gate dielectric layer 150. The first gate dielectric layer 140 and the second gate dielectric layer 150 may be deposited using conventional deposition processes including atomic layer deposition (ALD) or CVD processes. The source/drain regions 101 in the fin 130 may be grown with chemical vapor epitaxy, for example. A sacrificial layer 22 may be formed on the first and second gate dielectric layers 140 and 150. The sacrificial layer 22 may include a material such as TiN, for example, which may be deposited by any conventional deposition process such as CVD. Due to the deposition of the sacrificial layer 22 at this stage, subsequent active work-function metals formed for the first device 110 (n-type FinFET) and the second device 120 (p-type FinFET) will not negatively impact work-function characteristics or threshold voltages.

Referring to FIG. 5, in some embodiments, the fins 130 may be cut or etched by conventional semiconductor processing methods. A material layer 10 and the patterned mask layer 20 may be deposited on the sacrificial layer 22. The material layer 10 may be a resist stack including an optical planarization layer (OPL). An opening 20A in the patterned mask layer 20 may be formed by conventional lithographic process such as by exposure to light, followed by an etching process to provide an exposed portion 152 of the fin 130. The etching process of the TiN sacrificial layer 22 may include wet etch or dry etch processes based on hydrogen peroxide, and the etching process of dielectric materials may include HC1/DHF processes. The exposed portion 152 of the fin 130 may form an isolation cavity that exposes a surface 130S of the fin 130 in the cut region 160. In some embodiments, the cut region 160 of the fin 130 separates the first gate dielectric layer 140 and the second gate dielectric layer 150, with the first gate dielectric layer 140 remaining on the first device 110 (n-type FinFET), and the second gate dielectric layer 150 remaining on the second device 120 (p-type FinFET). The first gate dielectric layer 140 and the second gate dielectric layer 150 are discontinuous in the cut region 160 of the fin 130, and the first device 110 and the second device 120 do not share a common gate dielectric layer. Moreover, the fin 130 is cut before the deposition of high-work-function metals for the n-type and p-type FinFETs.

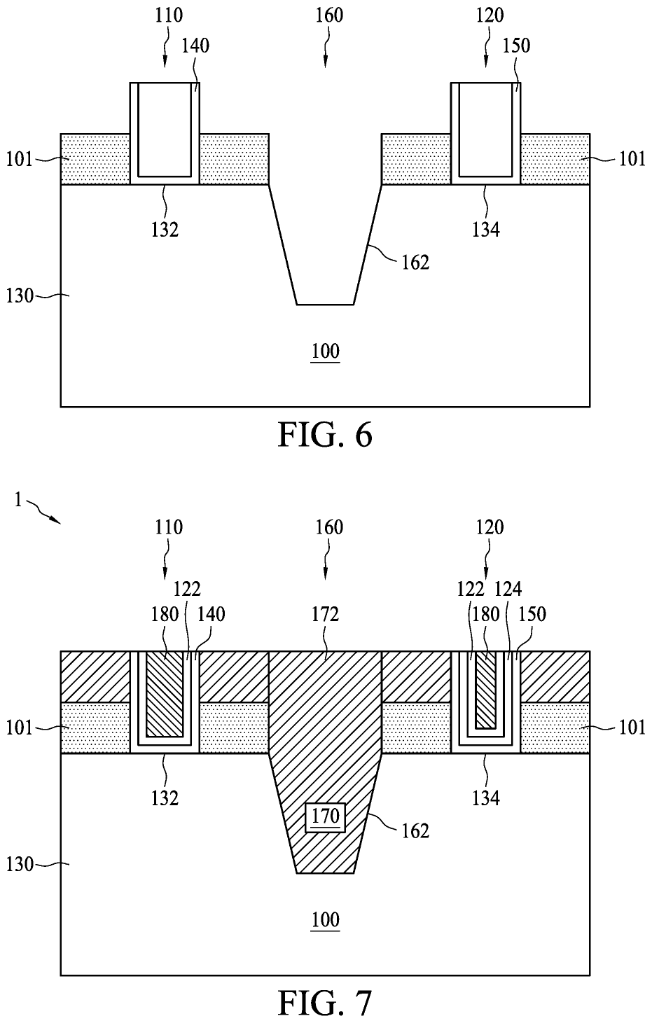

With reference to FIG. 6 and FIG. 7, in some embodiments, the exposed portion 152 of the fin 130 is etched to provide the cut region 160 within a trench 162 between the first device 110 and the second device 120, in which the second device 120 is adjacent to the first device 110. The etching process may be an anisotropic etching process through the exposed portion 152 of the fin 130 to remove a portion of the fin 130 and to define the trench 162. An overall depth of the trench 162 may vary depending on a particular application. In some embodiments, the trench 162 may have a depth that only removes a portion of the vertical height of the fin 130. In some embodiments, an insulator material 170 is disposed and filled in the cut region 160 of the fin 130. In some embodiments, a shallow trench isolation (STI) structure 172 may be formed in the insulator material 170. In some embodiments, as shown in FIG. 7, a gate electrode 122 is disposed on a high-work-function metal 124 of the second device 120 (p-type FinFET). The gate electrode 122 may also be disposed on the first gate dielectric layer 140, according to some embodiments. A gate metal 180 is then disposed on the gate electrode 122. One or more chemical mechanical planarization (CMP) processes may be performed to remove excess materials above the insulator material 170.

It should be noted that the insulator material 170 disposed in the cut region 160 of the fin 130 constitutes a diffusion break with the STI structure 172 of the active first and second devices 110 and 120. It should be further noted that certain layers and contacts in the semiconductor structure 1 have been omitted for clarity. For example, a gate cap layer (not shown) may be disposed on the gate metal 180. The gate cap layer may be formed by first performing a recess etching process to recess the gate metal 180 in order to make room for the gate cap layer. Thereafter, the gate cap layer may be formed above the recessed gate metal 180 by filling the remaining portions of the gate recessed gate metal 180 in the first device 110 and the second device 120 with the gate cap material. A CMP process may be performed to remove excess materials that drop onto the layer of insulating material 170. In another example, conductive contacts (not shown) may be formed in the insulator material 170 in order to provide electrical contact to the source/drain regions 101 of the active first and second devices 110 and 120. The conductive contacts may include a variety of different materials, such as tungsten. The conductive contacts may have any desired configuration, and may be formed using any suitable technique. In some instances, additional insulator material (not shown) may be formed above the insulator material 170, and the conductive contacts, connected to the source/drain regions 101, may be formed at or about the same time as a conductive contact (not shown) for the gate structures of the first and second devices 110 and 120. The conductive contacts may also be at least partially positioned in the same layer of insulator material 170 that forms the STI structure 172 in the cut region 160 of the fin 130.

Because the fins in the semiconductor structure of the present disclosure are not cut until after the source/drain regions are formed on the fins, it is preferable that the semiconductor material of the source/drain regions be consistent across all of the FinFET devices. Moreover, the isolation structures in the cut region of the fins are able to laterally isolate the active FinFET devices. In the semiconductor structure of the present disclosure, the first gate dielectric layer and the second gate dielectric layer are discontinuous in the cut region of the fins, and the FinFET devices do not share a common gate dielectric layer. The fins of the semiconductor structure are cut before the deposition of the high-work-function metals for the FinFET devices. Accordingly, diffusion of oxygen from the p-type FinFET devices to the n-type FinFET devices can be stopped, thereby enabling threshold voltage control for the FinFET devices in the semiconductor structure.

One aspect of the present disclosure provides a semiconductor structure, including a substrate, a first device, a second device, a fin, a first gate dielectric layer, a second gate dielectric layer, and a cut region of the fin. The second device is adjacent to the first device. The fin is disposed on the substrate between the first device and the second device. The first gate dielectric layer is disposed on a first portion of the fin, and the second gate dielectric layer is disposed on a second portion of the fin. The cut region of the fin is formed within a trench between the first device and the second device.

Another aspect of the present disclosure provides a method of forming a semiconductor structure, including providing a substrate;

forming a fin on the substrate; forming a first gate dielectric layer on a first portion of the fin; forming a second gate dielectric layer on a second portion of the fin; forming a patterned mask layer on the first gate dielectric layer and the second gate dielectric layer; and etching an exposed portion of the fin to provide a cut region within a trench between a first device and a second device, wherein the second device is adjacent to the first device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor structure, comprising:
a substrate;
a first device;
a second device adjacent to the first device;
a fin disposed on the substrate between the first device and the second device;
a first gate dielectric layer disposed on a first portion of the fin;
a second gate dielectric layer disposed on a second portion of the fin; and
a cut region of the fin within a trench between the first device and the second device; wherein the cut region includes a shallow trench isolation structure, and a top surface of the shallow trench isolation structure is coplanar with top surfaces of the first device and the second device.

2. The semiconductor structure of claim 1, wherein the first gate dielectric layer and the second gate dielectric layer comprise a high-k dielectric material.

3. The semiconductor structure of claim 1, wherein the cut region of the fin separates the first gate dielectric layer and the second gate dielectric layer, with the first gate dielectric layer remaining on the first device, and the second gate dielectric layer remaining on the second device.

4. The semiconductor structure of claim 3, wherein the first gate dielectric layer and the second gate dielectric layer are discontinuous in the cut region of the fin.

5. The semiconductor structure of claim 3, wherein the first device and the second device do not share a common gate dielectric layer.

6. The semiconductor structure of claim 1, wherein the first device is an n-type fin field-effect transistor (FinFET), and the second device is a p-type FinFET.

7. The semiconductor structure of claim 1, wherein an insulator material is disposed in the cut region of the fin.

8. The semiconductor structure of claim 7, wherein the shallow trench isolation structure is formed in the insulator material.

9. The semiconductor structure of claim 6, wherein a gate electrode is disposed on a high-work-function metal of the second device.

10. The semiconductor structure of claim 9, wherein a gate metal is disposed on the gate electrode.

11. The semiconductor structure of claim 6, wherein the cut region of the fin blocks an oxygen transport pathway from the p-type FinFET to the n-type FinFET.

12. The semiconductor structure of claim 6, wherein the cut region of the fin preserves a threshold voltage of the first device.

13. A method of forming a semiconductor structure, comprising:
providing a substrate;
forming a fin on the substrate;
forming a first gate dielectric layer on a first portion of the fin;
forming a second gate dielectric layer on a second portion of the fin;
forming a patterned mask layer on the first gate dielectric layer and the second gate dielectric layer;
etching an exposed portion of the fin to provide a cut region within a trench between a first device and a second device, wherein the second device is adjacent to the first device; and
forming a shallow trench isolation structure in the cut region, wherein a top surface of the shallow trench isolation structure is coplanar with top surfaces of the first device and the second device.

14. The method of claim 13, wherein the first gate dielectric layer and the second gate dielectric layer comprise high-k dielectric material.

15. The method of claim 13, wherein the cut region of the fin layer separates the first gate dielectric layer and the second gate dielectric layer, with the first gate dielectric layer remaining on the first device, and the second gate dielectric layer remaining on the second device.

16. The method of claim 13, wherein the first device is an n-type fin field-effect transistor (FinFET), and the second device is a p-type FinFET.

17. The method of claim 16, wherein an insulator material is disposed in the cut region of the fin.

18. The method of claim 17, wherein the shallow trench isolation structure is formed in the insulator material.

19. The method of claim 13, wherein a gate electrode is disposed on a high-work-function metal of the second device.

20. The method of claim 19, wherein a gate metal is disposed on the gate electrode.
